(19) United States
(12) Patent Application Publication
(10) Pub. No.: US 2012/0017967 A1
(43) Pub. Date: Jan. 26, 2012

(54) SERIES AND PARALLEL DYE-SENSITIZED SOLAR CELL MODULE

(76) Inventors: Byung-Moo Moon, Seoul (KR); Hyun-ju Kim, Gyeongsangnam-do (KR); Seon-hee Seo, Gyeongsangnam-do (KR)

(21) Appl. No.: 13/145,086

(22) PCT Filed: Jan. 18, 2010
(86) PCT No.: PCT/KR2010/000291

§ 371 Date: Jul. 18, 2011

(30) Foreign Application Priority Data
Jan. 19, 2009 (KR) 10-2009-0004262

(51) Int. Cl. H01L 31/05

(52) U.S. Cl. 136/244

(57) ABSTRACT

Provided is a series and parallel dye-sensitized solar cell module. The series and parallel dye-sensitized solar cell module includes a plurality of parallel modules, each including a plurality of positive electrodes aligned on a conductive transparent film of a positive electrode substrate, a plurality of negative electrodes aligned on a conductive transparent film of a negative electrode substrate, a redox electrolyte filled between the positive electrode and the negative electrode, a positive electrode grid formed on the conductive transparent film of the positive electrode substrate to distribute electrons to the positive electrode, and a negative electrode grid formed on the conductive transparent film of the negative electrode substrate to capture electrons generated from the negative electrode, and an insulator configured to insulate the plurality of parallel modules from each other. Here, the negative electrode grid included in one of the plurality of parallel modules is connected with the positive electrode grid included in a neighboring parallel module which is next to the parallel module by surface contact.

### CROSS-REFERENCE TO RELATED APPLICATION

This application claims priority to and the benefit of Korean Patent Application No. 2009-0004262, filed 19. 1. 2009, the disclosure of which is incorporated herein by reference in its entirety.

### BACKGROUND

1. Field of the Invention

The present invention relates to a dye-sensitized solar cell module, and more particularly, to a series and parallel dye-sensitized solar cell module in which a plurality of unit stripe cells are connected in series and parallel to generate high voltage and high current.

2. Discussion of Related Art

A solar cell, which is a photoelectric transformation element converting solar light into electric energy, is inexhaustible and environment-friendly, unlike other energy sources, and thus the importance of the solar cell is increasing with time.

Conventionally, a single crystal or polycrystalline silicon solar cell has been widely used as a solar cell. However, the silicon solar cell had a high production cost since large-scale equipment and raw materials used in manufacture thereof are expensive, and there was a limitation in improving a conversion efficiency of converting solar energy into electric energy. For these reasons, new alternatives have been sought after.

As an alternative to the silicon solar cell, much attention has been paid to a solar cell using an organic material, which may be prepared at a low cost, and particularly, a dye-sensitized solar cell having a very low production cost has attracted great attention. Hereinafter, a structure of a unit cell of the dye-sensitized solar cell will be described with reference to FIG. 1. FIG. 1 is a cross-sectional view illustrating a general structure of a unit cell of a dye-sensitized solar cell.

Generally, a unit cell of a dye-sensitized solar cell includes a counter electrode 10, an oxide semiconductor negative electrode 50 and a redox electrolyte 90 filled in a space between the two electrodes. The negative electrode 50 includes a transparent substrate 52, a conductive transparent film 54 attached to a bottom surface of the transparent substrate 52, and a porous film 56 attached to a bottom surface of the conductive transparent film 54. The porous film 56 is composed of metal oxide nanoparticles to which a photosensitive dye is adsorbed. The counter electrode 10 includes a transparent substrate 14, a conductive transparent film 16 attached to a top surface of the transparent substrate 14, and a conductive layer 12 attached to a top surface of the conductive transparent film 16 and composed of a conductive metal such as platinum, carbon nanotubes (CNTs) or a conductive polymer. The electrolyte 90 is air-tightly sealed by a partition 92 equipped between the negative electrode 50 and the counter electrode 10. The partition 92 is formed of a thermoplastic resin or a thermosetting resin.

When solar light is incident to the unit cell of the dye-sensitized solar cell formed as described above, light quanta are first absorbed into the photosensitive dye, and thus electrons in a valence band of the photosensitive dye are excited to a conduction band. The excited electrons are transferred to an external circuit through the conductive transparent film 54. Meanwhile, a site of the electrons which are released from the photosensitive dye is filled in such a manner that ions in the liquid electrolyte 90 receive electrons from the conductive layer 12 through an oxidation/reduction reaction and transfer the electrons to the photosensitive dye.

The dye-sensitized solar cell is manufactured in a module type in which unit cells are connected in series and parallel, as described above, to generate sufficient electric energy. Korean Patent Publication No. 10-2005-0102854 discloses a dye-sensitized solar cell module formed by connecting unit cells in series and parallel.

According to the above-mentioned publication, both a negative electrode and a counter electrode are formed on one substrate. Thus, the dye-sensitized solar cell of the publication in which both the positive electrode and counter electrode are formed is relatively complicated and inconvenient compared to when only one of a negative electrode and a counter electrode is formed on one substrate.

In addition, according to the above-mentioned publication, a lead line is used to connect serially connected unit cells in parallel. Thus, it is inconvenient that an additional process of equipping a lead line should be performed after the manufacture of the module is completed.

### SUMMARY OF THE INVENTION

The present invention is directed to providing a series and parallel dye-sensitized solar cell module in which unit stripe cells are connected in series and parallel during coupling of a positive electrode substrate with a negative electrode substrate without an additional process.

In one aspect, a series and parallel dye-sensitized solar cell module includes: a plurality of parallel modules, each including a plurality of positive electrodes aligned on transparent conductive layer of a positive electrode substrate, a plurality of negative electrodes aligned on a transparent conductive layer of a negative substrate, a redox electrolyte filled between the positive electrode and the negative electrode, a positive electrode grid formed on the transparent conductive layer of the positive electrode substrate to distribute electrons to the positive electrode, and a negative electrode grid formed on the transparent conductive layer of the negative electrode substrate to capture electrons generated from the negative electrode; and an insulator configured to insulate the plurality of parallel modules from each other. The negative electrode grid included in any of the plurality of parallel modules is connected with the positive electrode grid included in a neighboring parallel module next to the any of the plurality of parallel modules by surface contact.

The parallel module may include a sealant which prevents the positive and negative electrode grids from being eroded by the redox electrolyte and insulates the positive electrode grid from the negative electrode grid.

The positive electrode grid may include a positive electrode busbar extending along an alignment direction of the positive electrode and a distributor extending between the plurality of positive electrodes from the positive electrode busbar, and the negative electrode grid may include a negative electrode busbar extending along an alignment direction of the negative electrode and a capturer extending between the plurality of negative electrodes from the negative electrode busbar. The positive electrode busbar and the negative electrode busbar may be disposed at opposite sides based on the parallel module and extend in opposite directions.

Here, the negative electrode busbar of the negative electrode grid included in the any of the plurality of parallel modules and the positive electrode busbar of the positive electrode grid included in the neighboring parallel module may be disposed at the same side based on the parallel modules. One of the positive and negative electrode busbars preferably has a length capable of passing through the insulator and overlapping the other one.

The insulator may include a positive electrode groove formed by etching the transparent conductive layer of the positive electrode substrate and a negative electrode groove formed by etching the transparent conductive layer of the negative electrode substrate to face the positive electrode groove, and may not be formed in sites to which the positive electrode grid and the negative electrode grid are attached. Here, the positive electrode groove may include a horizontal groove extending from a left end to a right end of the positive electrode substrate and a vertical groove extending from a top to a bottom of the positive electrode substrate. The horizontal grooves are preferably formed in the top and bottom of the parallel modules, and the vertical grooves are preferably formed between the parallel modules.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a cross-sectional view illustrating a general structure of a unit cell of a dye-sensitized solar cell;

FIG. 2 is a projected plan view illustrating an exemplary embodiment of a series and parallel dye-sensitized solar cell module according to the present invention;

FIG. 3 is a projected plan view illustrating a negative electrode substrate and components formed thereon of the series and parallel dye-sensitized solar cell module of FIG. 2;

FIG. 4 is a plan view illustrating a positive electrode substrate and components formed thereon of the series and parallel dye-sensitized solar cell module of FIG. 2;

FIG. 5 is a partial cross-sectional view taken along line A-A′ of FIG. 2; and

FIG. 6 is a partial cross-sectional view taken along line B-B′ of FIG. 2.

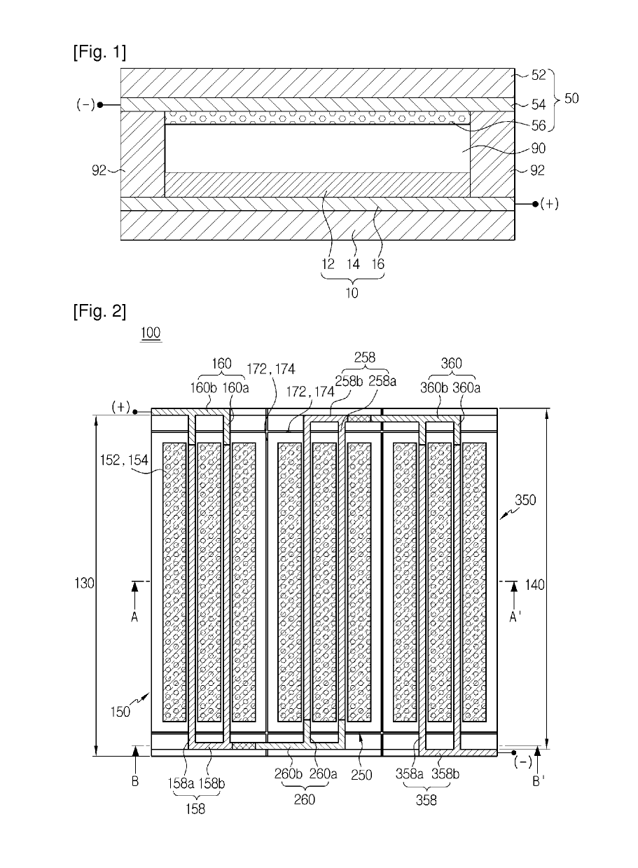

### DETAILED DESCRIPTION OF EXEMPLARY EMBODIMENTS

Hereinafter, exemplary embodiments of a series and parallel dye-sensitized solar cell module according to the present invention will be described in detail with reference to the accompanying drawings. Prior to the description, it should be understood that technical terms or words used in the specification and appended claims should not be interpreted with a limited, for example, conventional or dictionary, meaning, and the present invention should be interpreted with meanings and notions corresponding to the scope of the present invention according that the inventor can define notions of terms appropriately to describe his/her invention by the utmost method. Since configurations shown in the exemplary embodiments herein and the drawings are merely the most preferably embodiments, not represent the scope of the present invention, it should be understood that there may be various equivalents and modifications capable of replacing theses configurations at the time of filing this application.

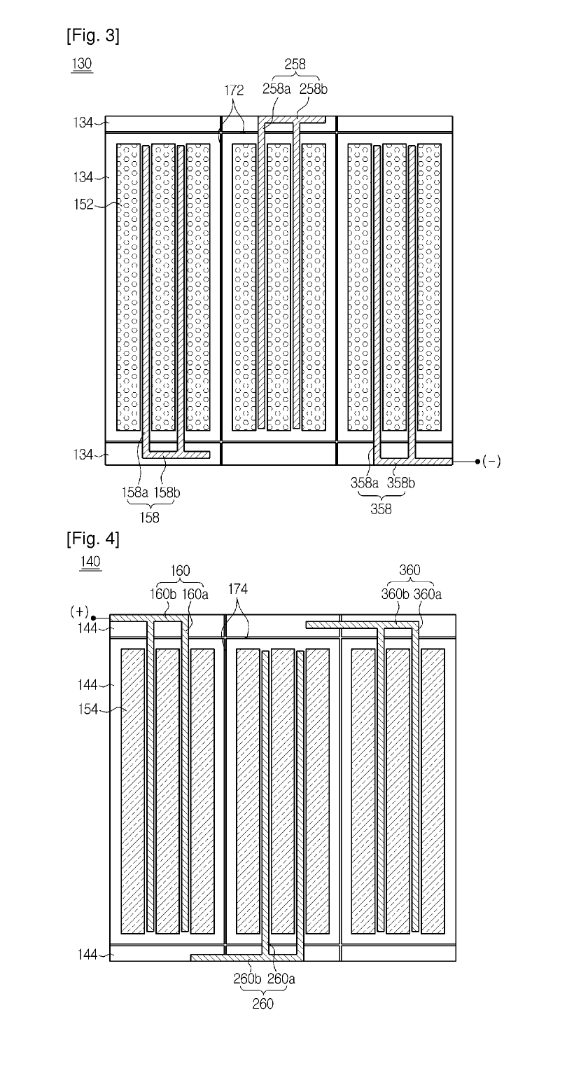

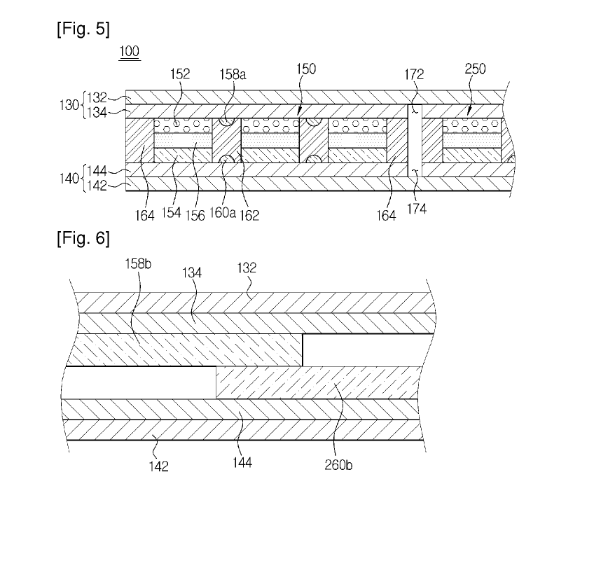

FIG. 2 is a projected plan view of a series and parallel dye-sensitized solar cell module according to an exemplary embodiment of the present invention, FIG. 3 is a projected plan view illustrating a negative electrode substrate and components formed thereon of the series and parallel dye-sensitized solar cell module of FIG. 2, FIG. 4 is a plan view illustrating a positive electrode substrate and components formed thereon of the series and parallel dye-sensitized solar cell module of FIG. 2, FIG. 5 is a partial cross-sectional view taken along line A-A′ of FIG. 2, and FIG. 6 is a partial cross-sectional view taken along line B-B′ of FIG. 2.

The series and parallel dye-sensitized solar cell module 100 according to the present invention includes a negative electrode substrate 130 and a positive electrode substrate 140, which face each other. As shown in FIG. 5, the negative electrode substrate 130 includes a transparent substrate 132 and a transparent conductive layer 134, and the positive electrode substrate 140 includes a transparent substrate 142 and a transparent conductive layer 144. The transparent substrate 132 or 142 may be a transparent glass substrate, for example, formed of soda lime glass or borosilicate glass, or a transparent plastic substrate, for example, formed of polyethylene terephthalate (PET), polyethylene naphthalate (PEN), polycarbonate (PC), polypropylene (PP), polyimide (PI) or triallyl cyanurate (TAC). The transparent conductive layer 134 or 144 may be formed of tin-doped indium oxide (ITO), fluorine-doped tin oxide (FTO), zinc oxide (ZnO), antimony-doped tin oxide (ATO) or tin oxide (TO). The transparent conductive layer 134 or 144 is coated on the transparent substrate 132 or 142 by a process such as sputtering, chemical vapor deposition (CVD) or spray pyrolysis deposition (SPD).

A plurality of parallel modules 150, 250 and 350 are aligned in parallel between the negative electrode substrate 130 and the positive electrode substrate 140, and insulated from each other by an insulator. FIG. 2 shows only three parallel modules 150, 250 and 350, but it is reasonable for the number of the parallel modules to be more or less than three. Hereinafter, configurations of the parallel modules 150, 250 and 350 will be described in detail. Here, the configurations of the parallel modules 150, 250 and 350 are the same as each other, and thus only the parallel module 150 will be described.

The parallel module 150 includes a plurality of negative electrodes 152, a plurality of positive electrodes 154, a redox electrolyte 156, a negative electrode grid 158, a positive electrode grid 160, an internal sealant 162 and an external sealant 164.

The plurality of negative electrodes 152 are aligned in parallel on the transparent conductive layer 134 of the negative electrode substrate 130 as shown in FIGS. 3 and 5, and composed of nanoparticles of a metal oxide (titania, etc.) and a photosensitive dye adsorbed to a surface of the nanoparticles. As the photosensitive dye, a material such as a compound formed in a metal complex of aluminum (Al), platinum (Pt), palladium (Pd), europium (Eu), lead (Pb) or iridium (Ir) or a ruthenium (Ru) complex is used. The negative electrode 152 is formed by applying a paste in which the nanoparticles of the metal oxide are dispersed to the transparent conductive layer 134 of the negative electrode substrate 130 using a process such as doctor blading or screen printing, followed by subjecting the paste to thermal treatment.

The plurality of positive electrodes 154 are aligned in parallel on the transparent conductive layer 144 of the positive electrode substrate 140 as shown in FIGS. 4 and 5 to face the negative electrode 152, and composed of a conductive metal such as Pt, carbon nanotubes (CNTs) or a conductive polymer. The positive electrode 154 is formed by applying a conductive metal, CNTs or a conductive polymer onto the transparent conductive layer 144 of the positive electrode substrate 140 using a process such as electroplating, sputtering or doctor blading, followed by subjecting the conductive metal, CNTs or conductive polymer to thermal treatment.

FIGS. 2 to 5 show the parallel module 50 including three negative electrodes 152 and three positive electrodes 154. However, it is reasonable for the parallel module 150 to include more or fewer negative electrodes 152 and positive electrodes 154.

The redox electrolyte 156 is filled between the negative electrode 52 and the positive electrode 154. The electrolyte 156 serves to receive electrons from the positive electrode 154 through an oxidation/reduction reaction and transfer the electrons to the photosensitive dye of the negative electrode 152.

The negative electrode 152, the positive electrode 154 and the electrolyte 156 constitute a unit stripe cell. Thus, the parallel module 150 includes a plurality of unit stripe cells, which have an electric parallel relationship in the parallel module 150. However, when the parallel module 150 just includes a plurality of unit stripe cells, there is a limitation that the parallel module 150 generates high current. Therefore, the parallel module 150 includes a negative electrode grid 158 and a positive electrode grid 160.

The negative electrode grid 158 is attached to the transparent conductive layer 134 of the negative electrode substrate 130 to capture electrons generated from the negative electrode 152 and lead the electrons out of the parallel module 150. As shown in FIG. 3, the negative electrode grid 158 includes a capturer 158a and a negative electrode busbar 158b, and is formed of a conductive material. The negative electrode busbar 158b extends along an alignment direction of the negative electrode 152 from the outside of the parallel module 150. The capturer 158a extends between the plurality of negative electrodes 152 from the negative electrode busbar 158b. The negative electrode busbar 158b and a negative electrode busbar 258b of the neighboring parallel module 250 next to the parallel module 150 are disposed at opposite sides based on the plurality of negative electrodes 152 as shown in FIG. 3. For example, the negative busbar 158b is disposed below the plurality of negative electrodes 152 and the negative busbar 258b is disposed above the plurality of negative electrodes 152. The electrons captured by the capturer 158a are transferred to the negative busbar 158b).

The positive electrode grid 160 is attached to the transparent conductive layer 144 of the positive electrode substrate 140 to distribute electrons provided from the outside of the parallel module 150 to the positive electrode 154. The positive electrode grid 160 includes a distributor 160a and a positive electrode busbar 160b as shown in FIG. 4, and is composed of a conductive material. The positive electrode busbar 160b extends along an alignment direction of the positive electrode 154, and the distributor 160a extends between the plurality of positive electrodes 154 from the positive electrode busbar 160b. Here, the positive electrode busbar 160b is disposed at an opposite side of the negative electrode busbar 158b based on the parallel module 150 as shown in FIG. 2, and extends in an opposite direction to the extension direction of the negative electrode busbar 158b.

The positive electrode busbar 260b of the neighboring parallel module 250 next to the parallel module 150 is disposed at an opposite side of the positive electrode busbar 160b based on the plurality of positive electrodes 154 as shown in FIG. 4. For example, the positive electrode busbar 160b is disposed above the plurality of positive electrodes 154, and the positive electrode busbar 260b is disposed below the plurality of positive electrodes 154. The electrons transferred to the distributor 160a through the positive electrode busbar 160b are distributed to the positive electrode 154.

Meanwhile, the negative electrode busbar 158b is electrically connected with the positive electrode busbar 260b of the positive electrode grid 260 included in the neighboring parallel module 250 next to the parallel module 150 as shown in FIG. 2. In addition, the neighboring parallel module 250 is connected with another parallel module 350 adjacent thereto in the same manner as described above. As a result, the plurality of parallel modules 150, 250 and 350 are in electrically serial connection with each other. Here, the negative electrode busbar 158b and the positive electrode busbar 260b may be connected by surface contact as shown in FIGS. 2 and 6. To this end, the positive electrode busbar 260b passes through the insulator and extends to a point at which the positive busbar 260b may overlap the negative electrode busbar 158b. In this case, since the connection between the negative electrode busbar 158b and the positive electrode busbar 260b is naturally made by heat and pressure applied when the negative electrode substrate 130 is coupled to the positive electrode substrate 140, it is unnecessary to perform a process of separately equipping a lead line to connect the plurality of parallel modules 150, 250 and 350 with each other in series after the manufacture of the module 100 is completed. That is, the series and parallel dye-sensitized solar cell module may be very easily manufactured.

The internal sealant 162 is disposed between the capturer 158a and the distributor 160a as shown in FIG. 5 to prevent the capturer 158a and the distributor 160a from being eroded by the electrolyte 156 and insulate the capturer 158a from the distributor 160a. It is reasonable for the prevention of the erosion of the capturer 158a and the distributor 160a and the insulation of the capturer 158a from the distributor 160a to be achieved using other known methods. In addition, the external sealant 164 is disposed between an edge of the transparent conductive layer 134 of the negative electrode substrate 130 and an edge of the transparent conductive layer 144 of the positive electrode substrate 140 to prevent the electrolyte 156 from being leaked out of the parallel module 150, as shown in FIG. 5. The internal and external sealants 162 and 164 are formed of a thermoplastic or thermosetting resin.

An insulator includes a negative electrode groove 172 formed by etching the transparent conductive layer 134 of the negative electrode substrate 130 and a positive electrode groove 174 formed by etching the transparent conductive layer 144 of the positive electrode substrate 140. The grooves 172 and 174 are formed by a process such as laser etching, dry etching or wet etching.

The positive electrode groove 174 includes a horizontal groove extending from a left end to a right end of the positive electrode substrate 140 and a vertical groove extending from a top to a bottom of the positive electrode substrate as shown in FIG. 4. The horizontal grooves are formed in tops and bottoms of the parallel modules 150, 250 and 350. Specifically, the horizontal grooves are formed between the parallel modules 150, 250 and 350 and the positive electrode busbars 160b and 260b of the positive electrode grid 160. The vertical grooves are formed between the parallel modules 150, 250 and 350.

The negative electrode groove 172 is formed to correspond to the positive electrode groove 174 as shown in FIG. 3. The grooves 172 and 174 are not formed at sites to which the grids 158 and 160 are attached, respectively. When the grooves 172 and 174 are formed in the same pattern as described above, the insulator is easily formed due to the simple pattern.

Meanwhile, as shown in FIG. 2, the positive electrode substrate 140 and the negative electrode substrate 130 are dislocated. The positive electrode busbar 160b connected with an external circuit is relatively closer to the end of the positive electrode substrate 140 than another positive electrode busbar 360b, and the negative busbar 358b connected with an external circuit is relatively closer to the end of the negative electrode substrate 130 than another negative electrode busbar 158b. Thus, though the coupling of the positive electrode substrate 140 to the negative electrode substrate 130 is completed, the positive electrode busbar 160b and the negative electrode busbar 358b connected with external circuits, respectively, are exposed to the outside, and therefore the module 100 may be easily connected with an external circuit.

Hereinafter, procedures of manufacturing the series and parallel dye-sensitized solar cell module 100 will be described.

First, an insulator is formed by etching a transparent conductive layer 134 of a negative electrode substrate 130, and then a negative electrode grid 158 and a negative electrode 152 are formed on the transparent conductive layer 134. At the same time as or after the above-mentioned procedure, an insulator is formed by etching a transparent conductive layer 144 of a positive electrode substrate 140, and then a positive electrode grid 160 and a positive electrode 154 are formed on the transparent conductive layer 144.

After the above-mentioned work is completed, an internal sealant 162 and an external sealant 164 which are in a paste or film state are applied to a surface of the negative electrode substrate 130 or positive electrode substrate 140, and then the both substrates 130 and 140 are aligned. Afterward, sides of the negative electrode substrates 130 and the positive electrode substrates 140 are pressed during thermal treatment. During the thermal pressure, surface contact is made between a negative electrode busbar 158b of a negative electrode grid 158 included in a parallel module 150 and a positive electrode busbar 260b of a positive electrode grid 260 included in a neighboring parallel module 250, and therefore an electric serial relationship is created between the parallel module 150 and the neighboring parallel module 250. After the thermal pressure is completed, an electrolyte is inserted between the negative electrode 152 and the positive electrode 154, and then sealed.

According to the present invention, since a plurality of parallel modules formed in such a manner that unit stripe cells are connected in parallel are naturally connected in series when a negative electrode substrate and a positive electrode substrate are coupled to each other, it is unnecessary to perform an additional process of equipping a lead line to complete series and parallel connections between the unit stripe cells after the coupling of the positive and negative electrode substrates are completed. Thus, a series and parallel dye-sensitized solar cell module is very easily manufactured.

While the invention has been shown and described with reference to predetermined exemplary embodiments thereof, it will be understood by those skilled in the art that various changes in form and details may be made therein without departing from the scope of the invention as defined by the appended claims.

What is claimed is:

1. A series and parallel dye-sensitized solar cell module, comprising:
a plurality of parallel modules, each comprising a plurality of positive electrodes aligned on a transparent conductive layer of a positive electrode substrate, a plurality of negative electrodes aligned on a transparent conductive layer of a negative electrode substrate, a redox electrolyte filled between the positive electrode and the negative electrode, a positive electrode grid formed on the transparent conductive layer of the positive electrode substrate to distribute electrons to the positive electrode, and a negative electrode grid formed on the transparent conductive layer of the negative electrode substrate to capture electrons generated from the negative electrode; and
an insulator configured to insulate the plurality of parallel modules from each other,
wherein the negative electrode grid included in any of the plurality of parallel modules is connected with the positive electrode grid included in a neighboring parallel module which is next to the any of the plurality of parallel modules by surface contact.

2. The series and parallel dye-sensitized solar cell module according to claim 1, wherein the parallel module comprises a sealant for not only preventing the positive and negative electrode grids from being eroded by the redox electrolyte but also insulating the positive electrode grid from the negative electrode grid.

3. The series and parallel dye-sensitized solar cell module according to claim 1, wherein the positive electrode grid comprises a positive electrode busbar extending along an alignment direction of the positive electrode and a distributor extending between the plurality of positive electrodes from the positive electrode busbar,
the negative electrode grid comprises a negative electrode busbar extending along an alignment direction of the negative electrode and a capturer extending between the plurality of negative electrodes from the negative electrode busbar, and
the positive and negative electrode busbars are disposed at opposite sides with respect to the parallel module and extend in opposite directions.

4. The series and parallel_dye-sensitized solar cell module according to claim 3, wherein the negative electrode busbar of the negative electrode grid included in the any of the plurality of parallel modules and the positive electrode busbar of the positive electrode grid included in the neighboring parallel module are disposed at the same side as each other with respect to the parallel module, and one of the busbars has a length capable of passing by the insulator and overlapping the other busbar.

5. The series and parallel dye-sensitized solar cell module according to claim 1, wherein the insulator comprises a positive electrode groove formed by etching the transparent conductive layer of the positive electrode substrate and a negative electrode groove formed by etching the transparent conductive layer of the negative electrode substrate to face the positive electrode groove, and the insulator is not formed at sites in which the positive electrode grid and the negative electrode grid are attached.

6. The series and parallel dye-sensitized solar cell module according to claim 5, wherein the positive electrode groove comprises a horizontal groove extending from a left end to a right end of the positive electrode substrate and a vertical groove extending from a top to a bottom of the positive electrode substrate, the horizontal grooves being formed in the tops and bottoms of the parallel modules, and the vertical grooves being formed between the parallel modules.
